(19) United States
(12) Patent Application Publication
(10) Pub. No.: US 2015/0102702 A1
(43) Pub. Date: Apr. 16, 2015

(54) THERMAL POWER CELL AND APPARATUS BASED THEREON

(71) Applicants: Peter Jeney, Zug (CH); Gustav Hans Weber, Freienstein (CH)

(72) Inventors: Peter Jeney, Zug (CH); Gustav Hans Weber, Freienstein (CH)

(21) Appl. No.: 14/399,215

(22) PCT Filed: May 8, 2012
(86) PCT No.: PCT/EP2012/058472

§ 371 Date: Nov. 6, 2014

(51) Int. Cl. H01L 37/02

(52) U.S. Cl. CPC H01L 37/02; H01L 37/025
USPC 310/306

(57) ABSTRACT

Apparatus (100) comprising a device (10) with
a first electrically conducting electrode (11),
a second electrically conducting electrode (12), said electrodes (11, 12) being spaced apart,
a pyro-electric material (13) to which said electrodes (11, 12) are attached/applied,
at least one heat-exchanging structure (14) being thermally coupled to said pyro-electric material (13),
   said apparatus (100) further comprising
an electric oscillator circuitry (20),
   said device (10) being electrically connectable to the electric oscillator circuitry (20) so as to provide an oscillation of said pyro-electric material (13).

### CROSS REFERENCE TO RELATED APPLICATIONS

This application is entitled to the benefit of and incorporates by references subject matter disclosed in International Patent Application No. PCT/EP2012/058472, filed on May 8, 2012.

The invention relates to a device and apparatus which is designed to turn heat into electricity.

There are many technical and chemical processes which produce heat. In some cases this heat has to be removed from the process in order to make sure that the process as such is kept in the desired temperature regime. A lot of energy is typically wasted if the heat produced is not used.

There are a number of approaches where the off-heat produced by a process is used for heating purposes, for instance. This requires, however, that the building to be heated by the off-heat is not located too far away from the place where the heat is generated. There are still no means for efficiently transporting heat across larger distances.

There is an existing need for solutions which make it possible to harvest much of the wasted heat by turning it into usable electricity. If the heat could be turned into electricity in an efficient manner, the respective energy would not be lost and the energy could be fed into existing power grids, for example.

The problem until today is the efficiency of these processes. Theory says that such conversion processes can never exceed the Carnot limit which limits the conversion of heat into work.

In case of a fuel powered car, for instance, about 60% of the energy produced by the combustion engine is not used. At the same time, cars require electric energy for its aggregates. Until now this electric energy is separately produced using a generator rather than using the off-heat. This examples illustrates how important it would be to find an efficient solution for turning heat into electricity.

Many researchers engage themselves in projects concerning the conversion of heat into work.

It is known in the art that the so-called Seebeck-effect can be used in order to gain electric energy from heat. Details about a respective electric generator are disclosed in the German newspaper article “Aus Freude am Sparen” [For enjoyment to save], by B. Strassmann, Die Zeit, 42/2008, Germany.

The publication “Turning heat to electricity” by David L. Chandler, MIT News Office, 18 Nov. 2009, describes the current state of the art before the publication discloses first details of a Quantum-coupled single-electron thermal to electric conversion scheme.

The German car manufacturer BMW is also active in this field, as for instance mentioned in the German article “Strom auch aus Abwärme” [Current also from off-heat], Auto Motor and Sport, 21 May 2998, page 140. According to this publication, BMW is apparently planning to place a special semiconductor around the exhaust pipe in order to convert heat into electricity.

A team of researchers at the Oak Ridge National Laboratory has published the scientific article “Development of MEMS based pyroelectric thermal energy harvesters”, S. R. Hunter at el., Proc. Of SPIE, Vol. 8035, 80350V-1, 2011. These researchers are proposing a MEMS (Microelectromechanical system) device which is operated at very low frequencies between 10 and 100 Hz and which has a thin film structure with a low thermal mass. The respective device has a bimaterial structure and a resonantly driven cantilever motion is used.

There is another approach described and claimed in the European Patent EP1074053 B1. The inventor/applicant Seibold describes a thermoelement or thermo-electric energy converter which apparently uses the Seebeck-effect.

The paper “On thermoelectric and pyroelectric energy harvesting”, G. Sebald et al., IOP Publishing, UK, Smart Materials and Structures, 18, 2009, 125006, reveals that pyroelectric schemes are more promising than thermoelectric schemes. It is also stated in this paper that non-linear approaches are more promising than linear approaches.

It is an object of the present invention to provide an efficient and robust thermal to electric conversion scheme which can be applied in many fields.

### SUMMARY OF THE INVENTION

According to the invention, an apparatus is provided with comprises a device with a first electrically conducting electrode, a second electrically conducting electrode, and a pyro-electric material to which said electrodes are attached/applied. The electrodes are spaced apart. The device or the apparatus further comprises at least one heat-exchanging structure which is (directly or indirectly) thermally coupled to the pyro-electric material. The apparatus further comprises an electric oscillator circuitry. The device is electrically connectable to the electric oscillator circuitry so as to provide an oscillation of said pyro-electric material.

All embodiments preferably comprise a first oscillator and a second oscillator being coupled by means of conductive connections so that these two oscillators can be caused to jointly oscillate.

The first oscillator and second oscillator are preferably arranged in series. A transistor might be employed in-between to switch/control the connection between these two oscillators.

The invention uses the fact that in crystals and ceramic materials in addition to electric, thermal and mechanic fields there are synchronous electric signals. The invention further uses the fact that power can be transformed from one regime to another.

The device and apparatus of the present invention turns heat into electricity in a very efficient manner.

With the present invention heat can be converted into electricity so that it can be harnessed.

The invention make it possible to reclaim a significant portion of energy that is wasted so far.

The inventive technology makes it possible to build affordable devices.

The inventive technology makes it possible to “use” so-called low-grade heat in the temperature range between 15° C. and 600° C.

The present invention can be used to turn off-heat, solar heat, geothermal heat, ground heat, water heat as well as ambient heat into electricity.

### BRIEF DESCRIPTION OF THE DRAWINGS

Several possible embodiments of the invention will now be illustrated by way of example with reference to the accompanying drawings in which:

FIG. 1 is a schematic cross section of a first device in accordance with the present invention coupled to an oscillator;

FIG. 2 is a schematic cross section of a second device in accordance with the present invention;

FIG. 3 is a schematic diagram of a first apparatus comprising a device in accordance with FIG. 2;

FIG. 4 is a schematic diagram of a second apparatus comprising a device in accordance with FIG. 2;

FIG. 5A is a schematic diagram of the components of a third apparatus comprising four devices in a row during a mounting process;

FIG. 5B is a schematic diagram of the third apparatus comprising four devices in a row after the mounting process has been completed;

FIG. 5C is a schematic circuit diagram of the four devices of FIG. 5B arranged in series;

FIG. 5D is a schematic circuit diagram of the four devices of FIG. 5B arranged in parallel;

FIG. 6A is a schematic top view of a fourth apparatus comprising thirty-six devices in an array configuration;

FIG. 6B is a perspective view of the fourth apparatus of FIG. 6A;

FIG. 7 is a schematic cross section of another device in accordance with the present invention.

### DESCRIPTION OF THE PREFERRED EMBODIMENTS

The present invention concerns so-called heat traps.

The respective device 10 and apparatus 100 of the present invention turn heat into electricity in a very efficient manner. This is done by a charge displacement inside a solid state pyro-electric material 13 (preferably in the form of a crystal) of the device 10. According to the invention, this charge displacement is caused by heat (thermal expansion and electric polarization).

Pyroelectricity is the ability of certain materials to generate an electrical potential when they are heated or cooled. As a result of a change in temperature, positive and negative charges move to opposite ends through migration (i.e. the material 13 becomes polarized due to the charge displacements) and hence, an electrical potential is established. In this respect a pyro-electric material 13 behaves like a capacitor.

The composition and/or concentration of the pyro-electric material 13 of the present devices 10 is chosen such that it exhibits well pronounced pyroelectric properties without having any appreciable piezoeffect (a piezoelectric material exhibits electrical polarization when subjected to applied stress). At another composition and/or concentration, it manifests marked piezoelectric properties, but does not possess the pyroeffect.

The following materials are very well suited for all embodiments of the invention:
crystal boron silicate minerals
naturally occurring tourmaline;
strontium barium niobate (SBN);
barium titanate
lead magnesium niobium titanate, preferably in a sintered composition;
lead zirconate titanate (PTZ) ceramic or polarized lead zirconium titanate (PLZT), preferably lanthanum modified or doped. Well suited are hot-pressed PLZT ceramics.
Triglycine sulfate crystals (TGS), such as alanine-doped triglycine sulphate (ATGS);
Perowskit-Oxide crystals;
Polyvinyl idene fluoride (PVF₂) or polyvinyl fluoride (PVF) polymers.

More details of pyroelectric materials which might be suited are given in the paper “Pyroelectric materials, their properties and applications”, J. C. Joshi, A. L. Dawar, physica status solidi (a), Volume 70, Issue 2, pages 353-369, 16 Apr. 1982.

Very well suited for all embodiments of the invention are materials which have a pyroelectric coefficient p [10⁻⁸ C cm⁻² K⁻¹] larger than 2. Very advantageous are materials with a pyroelectric coefficient p [10⁻⁸ C cm⁻² K⁻¹] larger than 8.

Very well suited for all embodiments of the invention are materials which show primary pyroelectric and secondary pyroelectric effects. It is advantageous to employ materials which show both effects.

Preferred embodiments of the present invention use single-crystal, poly-crystalline or bulk pyro-electric materials 13 which have the special physical property of giving rise to two electrical poles of opposite signs at the extremities of these axes when they are subjected to a change in temperature. This is the phenomenon known under the name of pyro-electricity and the reverse effect is called electrocaloric effect, both reversible in nature. A much higher efficiency and frequency can be obtained. The electrical impulses applied to the device 10 are asymmetrical so as to produce an endothermal electrocaloric effect.

As compared to the invention, classical pyroelectrical devices use the direct pyro-electric effect by generating temperature oscillations from two heat baths by thermal switching. The present invention uses the reverse effect by producing temperature oscillations by electrical switching.

The pyro-electric materials 13 used in connection with the invention do not show electric or thermal flows but rather fields. Energy can be stored and released from these fields.

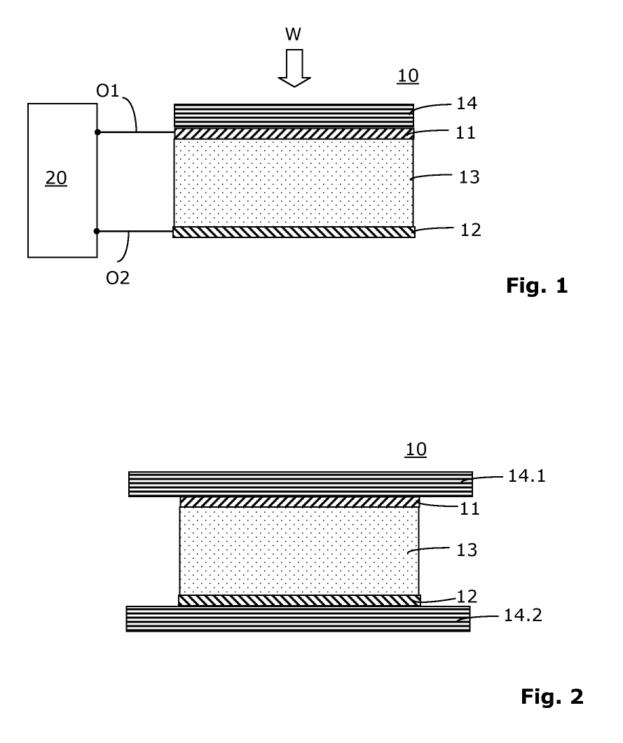

The pyro-electric material 13 of the device 10 is employed in or coupled to a high-gain electric oscillator circuitry 20, as illustrated in FIG. 1. If heat W is “applied” to the oscillating pyro-electric material 13 of the device 10, this heat is absorbed and the electrons are caused to transport/carry the “entropy”. The respective device 10 starts to build up and to gather or absorb heat W from the ambience or in case of the device of FIG. 1 from a heat-exchanging structure 14. The fact that the device 10 gathers or absorbs heat W is schematically illustrated in FIG. 1 by means of a block arrow. The heat W is trapped by the device 10 where it can only be converted into work (here work in the form of electricity), because the oscillation produces an overall endothermic reaction.

In the device 10 a thermal flow is established so that it has a negative recalescence, i.e. heat is absorbed actively. A negative recalescence means that the device 10 is gathering/absorbing ambient heat W (e.g. via the heat-exchanging structure 14). In order for this to happen, the device 10 is not operated in an equilibrium state but in a non-equilibrium state.

The device 10 comprises a first electrically conducting electrode 11 and a second electrically conducting electrode 12. These electrodes 11, 12 are spaced apart, as for instance illustrated in FIG. 1. The pyro-electric material 13 is in the present embodiment situated between the electrodes 11, 12. There is at least one heat-exchanging structure 14 which is thermally coupled to the pyro-electric material 13. The heat-exchanging structure 14 can be coupled directly to the pyro-electric material 13 or it can be coupled indirectly. FIG. 1 shows an embodiment with indirect coupling where the heat-exchanging structure 14 is positioned on top of the electrode 11 which sits on the pyro-electric material 13.

In all embodiments, the area of the electrodes 11, 12 and/or the heat-exchanging structure 14 can be smaller, larger or the same as the area of the pyro-electric material 13.

The electrodes 11, 12 can be arranged on one and the same side of the pyro-electric material 13 or they can be arranged on opposite sides of the pyro-electric material 13, provided they are spaced apart and not short circuited by a conductive connection.

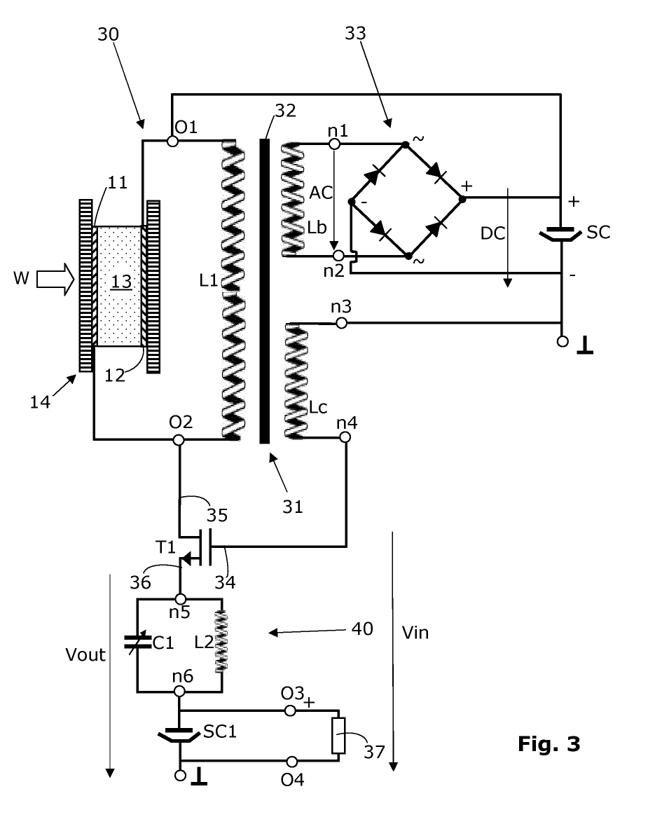

Another embodiment of the invention is shown in FIG. 2. The device 10 again comprises a first electrically conducting electrode 11 and a second electrically conducting electrode 12. These electrodes 11, 12 are spaced apart, as illustrated in FIG. 2. The pyro-electric material 13 is here situated between the electrodes 11, 12. There are two opposite heat-exchanging structures 14.1, 14.2 which are thermally coupled to the pyro-electric material 13. The area of the two opposite heat-exchanging structures 14.1, 14.2 is larger than the area of the electrodes 11, 12 and the material 13. The heat-exchanging structures 14.1, 14.2 can be coupled directly to the pyro-electric material 13 or they can be coupled indirectly. FIG. 2 shows an embodiment with indirect coupling where the heat-exchanging structures 14.1, 14.2 are positioned on top of the electrodes 11 and 12, respectively.

The heat-exchanging structure 14 or structures 14.1, 14.2 can have a size (area) which is smaller or larger (see FIG. 2) than the size of the respective electrodes 11, 12. The heat-exchanging structure 14 or structures 14.1, 14.2 can also have the same size as the respective electrodes 11, 12 (see FIG. 1).

The two electrodes 11, 12 can be made from different metals. In other words different metals (e.g. copper, aluminum, silver, aluminum or gold) are used for the electrode 11 and for the electrode 12.

The device 10 and/or the apparatus 100 in which the device 10 is employed might be encased by a housing (not shown) and/or they might be mounted on a carrier (substrate).

The device 10 further comprises a first electric output or node O1 connected or connectable to the first electrically conducting electrode 11 and a second electric output or node O2 connected or connectable to the second electrically conducting electrode 12. These two nodes O1, O2 can in all cases also be part of the electrodes 11, 12. Contact areas or pads of the electrodes 11, 12 can serve as nodes O1, O2.

The apparatus 100 comprises an electric oscillator circuitry 20 connected or connectable to the device 10. The respective electric contacts to the pyro-electric material 13 are established via the first and second electrically conducting electrodes 11, 12. The electric oscillator circuitry 20 is designed so as to initiate an oscillation of the pyro-electric material 13 of the device 10. The frequency of this oscillation is in the range between 5 kHz and 500 kHz. The frequency of this oscillation preferably is above 50 kHz. This applies to all embodiments. In most cases, the frequency of this oscillation is below 250 kHz.

The pyro-electric material 13 is caused to vibrate as a resonator, and its frequency of vibration determines the oscillation frequency of the first oscillator 30.

The electric oscillator circuitry 20 drives the device 10 in a non-linear mode, preferably by providing a descending slope (thermally and electrically) of the amplitude of the oscillation which brings the device 10 in the non-linear mode. This means that all embodiments of the invention use non-linear pyroelectric properties of the pyro-electric material 13.

The electric oscillator circuitry 20 is designed so that an asymmetric signal is obtained/applied which remains for a longer period of time in the under voltage and temperature regimes than at the over voltage and temperature regimes. Due to this asymmetric signal, during each oscillation cycle more energy is taken over or gathered than released. This leads to a situation where the oscillator circuitry 20 is effectively removing heat energy from the device 10 by drawing electrons of higher entropy from the material 13.

In all embodiments of the invention, the apparatus 100 interacts with the device 10 in a manner so that heat is absorbed so that the entropy is “loaded” onto electrons. And the electrons with increased entropy are caused to flow out of the material 13.

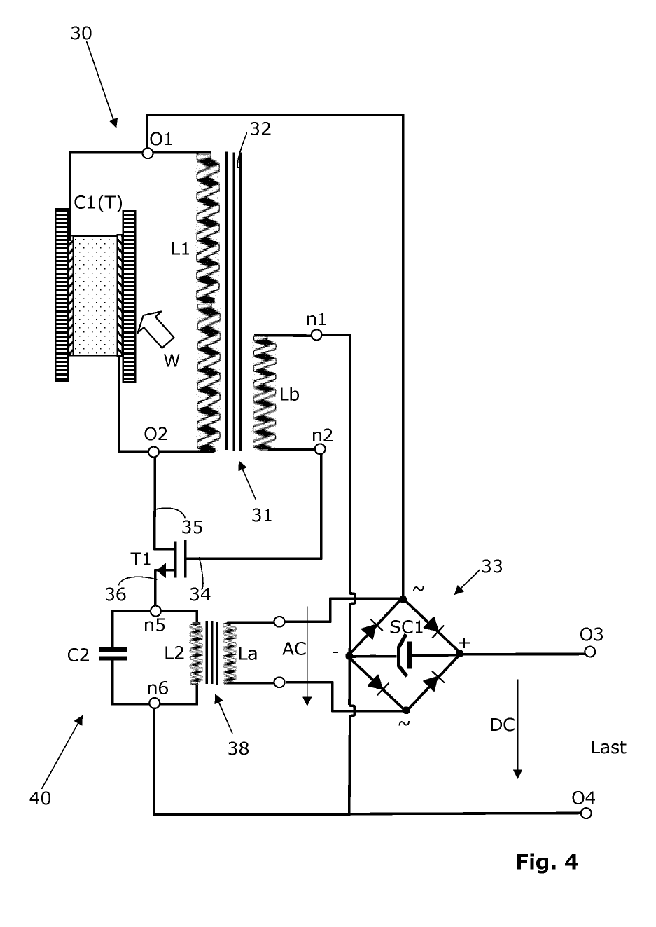

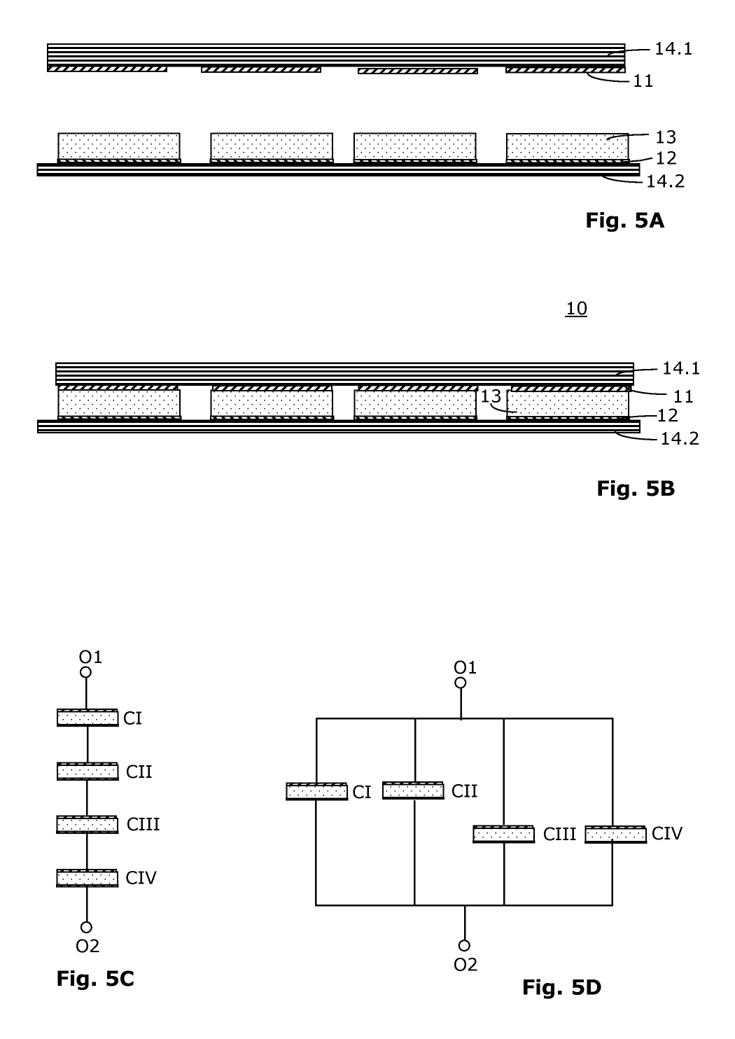

Most implementations and embodiments comprise an electric oscillator circuitry 20 with two oscillators 30 and 40, as will be described in connection with FIGS. 3 and 4. The two oscillators 30, 40 are connected so that a coupling of their oscillations occurs. The oscillator 40 serves in all embodiments as resonance circuit.

The electric oscillator circuitry 20 preferably in all embodiments comprises two coupled oscillators 30, 40 which are slightly de-tuned. In other words, the two oscillations have slightly different frequencies. The difference of the resonance frequencies (f1, f2) is between 5% and 0.1%. The de-tuning leads to an interference (called beat) between the two oscillations. This beat causes the creation of an internal drag from the pyro-electric material 13 to the electric oscillator circuitry 20 (i.e. from the oscillator 30 to the oscillator 40). This internal drag causes the electrons with increased entropy to flow out of the material 13.

Preferably all embodiments comprise two de-tuned oscillators 30, 40 where the device 10 is part of one of these oscillators (in FIGS. 3 and 4 the device 10 is part of the oscillator 30).

For the purposes of the present patent application an oscillator 30, 40 is an electronic circuit that produces a repetitive electronic signal.

Due to the fact that there is an interference caused between the two coupled oscillators 30, 40, the heat or entropy is “loaded” onto the electrons in a very efficient manner.

The apparatus 100 is considered to be an active apparatus since it actively cools the heat-exchanging structure 14 by loading the heat or entropy onto the electrons and by removing the electrons by means of the internal drag mentioned. The invention thus is based on the formation or a so-called cold-trap.

One of the two coupled oscillators 30, 40 is regarded to be in a so-called 3K bath, where 3K means 3 Kelvin, i.e. there is only radiation into the space at 3K (background radiation). The respective other of the two coupled oscillators 30, 40 is at the temperature of the heat exchanger 14, i.e. this oscillator 30 or 40 is at the surrounding temperature between 15° C. and 600° C. The electrons flowing through the first oscillator 30 are considered to act as heat or entropy carriers. Hence, the first oscillator 30 is deemed to be at the surrounding temperature between 15° C. und 600° C. while the other oscillator 40 is deemed to be in the 3K-bath.

Explained with other words, non-linear asymmetric electric impulses are applied to the pyro-electric material 13 of the device 10 so as to capture a quantum of heat or entropy per oscillation cycle. The quantum of heat or entropy is converted/transformed into an amount of impulse energy so that the oscillation is maintained and transferred into an amount of impulse energy made available at an output O3-O4 of the apparatus 100.

The device 10 and apparatus 100 of the invention can be activated/driven/powered by heat from any source, provided this heat is in the useable temperature range between 15° C. und 600° C.

There is no theoretical limit to the size of the device 10. However, there is a practical limitation based on the proposed application, manufacturing process, transportation and installation requirements.

Due to the unique nature of the device 10, it can be fabricated to meet the requirements of the application. For example it can be produced in a curved shape to fit around water or exhaust pipes or it can be manufactured with a flat structure (like in FIG. 1, for instance), to be used on a flat surface (e.g. inside a solar panel). The device 10 can also be integrated in an array.

All apparatus 100 in which one or more than one device 10 is/are employed are closed cycle implementations. This means that there are no air or liquid emissions or pollutions.

A first apparatus 100 of the invention is illustrated in FIG. 3. The apparatus 100 comprises one device 10 which is, for the sake of simplicity, the same device 10 as in FIG. 2. The device 10 comprises a first electrically conducting electrode 11 and a second electrically conducting electrode 12. These two electrodes 11, 12 are spaced apart. They can either be situated at opposite sides of the pyro-electric material 13 or they can be positioned at the same side of the pyro-electric material 13. There are two heat-exchanging structures 14.1, 14.2 which are thermally coupled to the pyro-electric material 13. In case of the present embodiment, the heat-exchanging structures 14.1, 14.2 are coupled via the respective electrodes 11, 12 to the pyro-electric material 13. This means that the heat exchange is here taking place through the electrodes 11, 12.

The device 10 forms together with a first inductor L1 an oscillator 30 (also called first oscillator), as shown in FIG. 3. In the present embodiment, the first inductor L1 is one of the coils or windings of a transformer 31.

In all embodiments of the invention, an air-core transformer or an iron-core or a ferrite-core transformer can be used as transformer 31. In FIG. 3 a transformer with a core 32 is shown. The first inductor L1 of the transformer 31 is magnetically coupled with the two other inductors Lb and Lc. Depending on the size of the coils L1, Lb, Lc one can obtain different voltages and currents, as needed for the respective apparatus 100. Actually, the ratio of the voltages depends on the number of primary coil windings of inductor L1 versus the number of secondary windings of the inductors Lb and Lc. Here the inductors Lb and Lc have fewer turns (windings) than the inductor L1. This means that the transformer 31 acts as step down transformer from the left to the right. A step down transformer has a construction that provides less voltage in the secondary circuit Lb and Lc than in the primary circuit L1.

As mentioned above, the device 10 is caused to oscillate. This means that an alternating (AC) voltage is provided at the primary winding (inductor L1) of the transformer 31. The transformer 31 generates an alternating magnetic field that is sensed (induced into) the other coils (inductor Lb and Lc). The inductor Lb and the inductor Lc both generate AC voltages whose waveforms are the same as the waveform of the primary voltage at the inductor L1. The amplitudes of the AC voltages generated by the inductors Lb and Lc depend on the respective ratios of turns. The voltages also depend on the core material, the driving frequency and coupling.

In the following an example is given: The inductor L1 might have 6 turns, the inductor Lb 12 turns and the inductor Lc 24 turns. This means that the transformer 31 acts as step up transformer from the left to the right.

In the embodiment of FIG. 3 a coupling transformer 31 is employed which couples the first oscillator 30 with a diode bridge rectifier 33. The rectifier 33 is coupled to the nodes n1 and n2 of the upper inductor Lb. One node n4 of the lower inductor Lc is connected to the gate 34 of a transistor T1 (e.g. a MOS-FET). The rectifier 33 is here employed for conversion of an alternating current (AC) input into a direct current (DC) output, as indicated in FIG. 3.

As illustrated in FIG. 3, a supercapacitor SC might be connected to the positive and negative nodes of the rectifier 33. A supercapacitor SC differs from a regular capacitor in that it has a very high capacitance. The supercapacitor SC stores energy by means of a static charge. The voltage of the supercapacitor SC is typically confined to 2.5V to 2.7V. In order to make sure that the DC voltage across the two nodes of the supercapacitor SC is in the right voltage range, the number of turns of the inductor Lb have to be selected accordingly.

In the present embodiment, the negative node of the supercapacitor SC is connected to ground. One node n3 of the inductor Lc is also connected to ground. The drain 35 of the transistor T1 is connected to the node O2 and the source 36 is connected to the electric oscillator circuitry 40. Instead of a field-effect-transistor (FET) a bipolar transistor T1 can be used. In case of a bipolar transistor T1 the gate 34 is referred to as base, the drain 35 is called collector and the source is called emitter.

The transistor T1 is employed to switch electronic signals. Here the transistor T1 provides for a selective coupling of the first oscillator 30 and the second oscillator 40. A small current or voltage at the gate terminal 34 controls or switches a much larger current between the drain 35 (collector) and source 36 (emitter) terminals of the transistor T1.

According to the invention, the transistor T1 might have a positive amplification factor. This means that the output voltage Vout will be higher than the input voltage Vin and the output current will be higher than the input current. The transistor T1 thus “pulls” current (electrons loaded with entropy) from the first oscillator 30 into the second oscillator 40. The transistor T1 could also act as a so-called follower where the signal at the source 36 follows the signal at the gate 34. In this case a small amount of “lifting power” is sufficient to raise the gate 34 and the source 36 rises with more strength. This means that the transistor T1, if used as follower, does not produce a higher output voltage but it does produce a higher output current which here would then flow into the oscillator 40.

The oscillator 40 might in all embodiments comprise a capacitor C1 (e.g. a variable capacitor) and an inductor L2 arranged in parallel, as shown in FIG. 3. As further depicted in FIG. 3, a supercapacitor SC1 might be connected between one node n6 of the oscillator 40 and ground. A load element 37 might be connected to the output nodes O3, O4, as depicted in FIG. 3.

Another embodiment of the invention is now described in connection with FIG. 4. Here again a device 10 together with an inductor L1 forms a first oscillator 30. The inductor L1 is one coil of the transformer 31. The transformer 31 comprises a second coil which is here referred to as inductor Lb. A first node n1 of the inductor Lb is connected to one node of a diode bridge rectifier 33 and to an output node O4 of a second oscillator 40. A second node n2 of the inductor Lb is connected to the gate 34 of a transistor T1. The transistor T1 is controlled/switched by the signal applied to its gate 34. If activated, the transistor T1 connects the node O2 of the first oscillator 30 with the node n5 of the second oscillator 40.

The second oscillator 40 comprises in the present embodiment a capacitor C2 and an inductor L2 arranged in parallel. The inductor L2 is part of a transformer 38. The second coil La of the transformer 38 provides an alternating voltage AC. This voltage AC is applied to the AC nodes of the rectifier 33, as shown in FIG. 4. The positive node of the rectifier 33 is connected to the positive output node O3 and the negative node of the rectifier 33 is, as mentioned, connected to the node n1 and to the output node O4. The lower node n6 of the second oscillator 40 is also connected to the output node O4. A supercapacitor SC1 is here placed between the two DC nodes of the rectifier 33, as shown in FIG. 4. Like in FIG. 3, this supercapacitor SC1 is located between the two output nodes O3, O4.

In all embodiments, the second oscillator 40 might comprise additional elements, such as capacitor diode, a transfer capacitor and a choking coil, for instance.

In all embodiments, the output voltage or current might be tapped from the first oscillator 30 or from the second oscillator 40.

In all embodiments, both oscillators 30 and 40 have a Q-factor which is greater than 1000.

The two oscillators 30, 40 are de-tuned so that a beat frequency is established. The second oscillator 40 “draws” energy (in the form of entropy-loaded electrons) from the first oscillator 30. Since heat (entropy) is loaded onto the electrons in the device 10, a certain drag is established which causes the device 10 to be cooled down (hence the expression cold trap) and more heat to be absorbed. The energy which is moved from the oscillator 30 to the oscillator 40 is used to load the supercapacitor SC1. The supercapacitor SC1 can be loaded if it is placed between the node n6 of the oscillator 40 and ground, as shown in FIG. 3, or it can be loaded via the transformer 31 and the rectifier 33, as shown in FIG. 4.

Due to the fact that the second oscillator 40 damps down the first oscillator 30, heat is flowing in a cyclic process into the device 10.

The apparatus 100 transforms this heat into electricity (here a DC voltage) which is being made available between the output nodes O3, O4.

Preferably, the two oscillators 30 and 40 of all embodiments are characterized by a small inductance L and a large capacitance C which results in a small T=L/C.

Preferably, the first oscillator 30 of all embodiments is a passive oscillator.

The supercapacitor SC1 might be employed in all embodiments in order to serve as an intermediate energy storage, but the supercapacitor SC1 is not absolutely necessary.

In all embodiments of the invention, the device 10, respectively the pyro-electric material 13, is collecting or absorbing heat Q either from the environment or from one or more heat-exchanging structures 14.

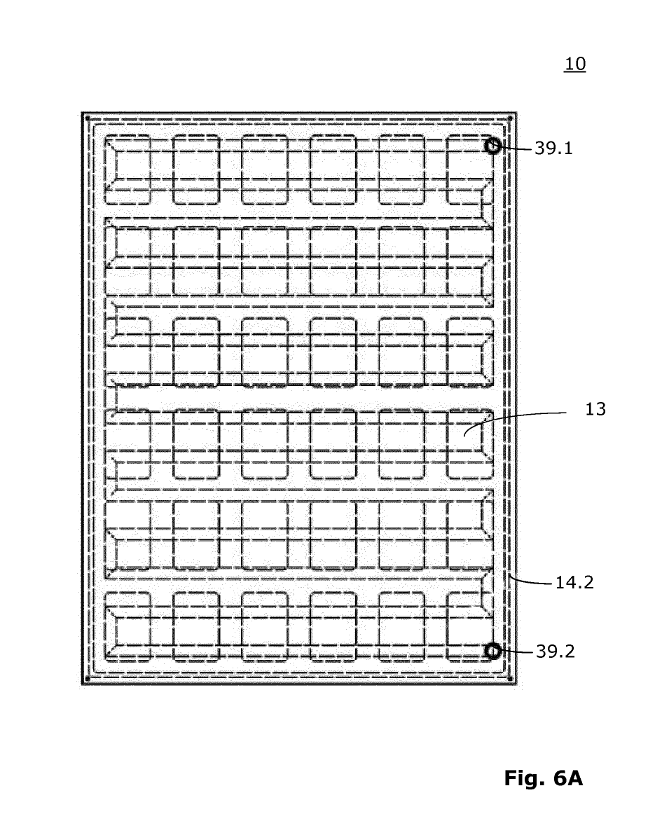

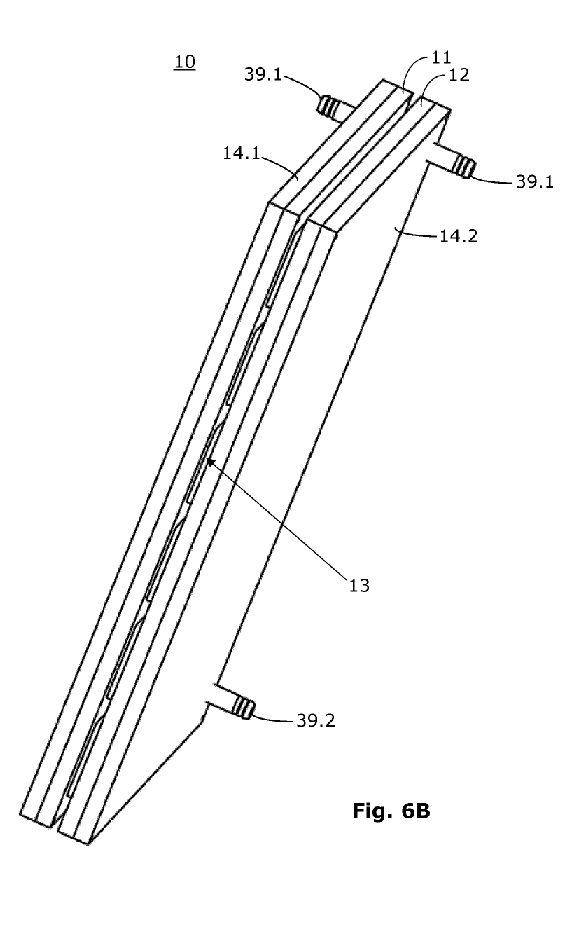

According to the present invention, two or more devices 10 can be arranged in rows, as shown in FIG. 5B, or they can be grouped in arrays, as shown in FIGS. 6A and 6B.

A device might comprise several pyro-electric material sections or areas 13. The example which is shown in FIGS. 5A and 5B shows a device 10 with four pyro-electric material sections or areas 13 arranged in a row. From the bottom to the top the device 10 might comprise a bottom heat-exchanging structure 14.2 which carries four electrodes 12 and four pyro-electric material sections or areas 13. Four counter electrodes 11 might be part of another heat-exchanging structure 14.1. FIG. 5A shows an exploded view before these elements are fitted together. FIG. 5B illustrates the device 10 after the heat-exchanging structure 14.1 with the four counter electrodes 11 has been positioned on top.

FIG. 5C shows a simplified circuit diagram where all four sub-devices are represented by capacitors CI, CII, CII and CIV. These capacitors CI, CII, CII, CIV can either be arranged in series, as shown in FIG. 5C, or they can be arranged in parallel, as shown in FIG. 5D.

FIG. 6A is a schematic top view of a fourth device 10 comprising thirty-six pyro-electric material sections or areas 13 in an array configuration. The array configuration has six rows and six columns. One of these pyro-electric material sections or areas 13 is marked with the reference number 13. Each of the pyro-electric material sections or areas 13 in this embodiment has a rectangular shape. There are a number of conductive connections in order to connect the individual pyro-electric material sections or areas 13 in series (similar to FIG. 5C) or in parallel (similar to FIG. 5D). The heat-exchanging structures 14.1 and/or 14.2 can be structured or they can carry a metallic pattern which serves as conductive connections.

It is also possible, as illustrated in FIG. 6B, to provide a first layer which serves first electrically conducting electrodes 11 and a second layer which serves second electrically conducting electrodes 12. The respective layers have to be patterned or structured so that they connect the pyro-electric material sections or areas 13 in series or in parallel.

The heat-exchanging structures 14, 14.1 and/or 14.2 of all embodiments might comprise channels for guiding a fluid (for instance water or oil) through the heat-exchanging structures 14, 14.1 and/or 14.2. As shown in FIGS. 6A and 6B, there might be access points 39.1, 39.2 which have a fluid connection to the channels mentioned. A fluid might be fed into the heat-exchanging structure 14.2 through the access point 39.1, for instance. The fluid then flows through the channels before it leaves the heat-exchanging structure 14.2 through the access point 39.2. In this case the access point 39.1 is the so-called hot end and the access point 39.2 the cold end. The fluid at the hot end is hotter than the fluid at the cold end. Heat W is transferred from the fluid through the material of the heat-exchanging structures 14, 14.1, 14.2 (and electrodes 11, 12 if positioned in-between) into the pyro-electric material sections or areas 13. Inside the pyro-electric material sections or areas 13 small quantities of the heat (entropy) are virtually transferred (loaded) onto the electrons, as described.

The devices 10 of FIGS. 5A, 5B and 6A, 6B might be used inside an apparatus 100, as illustrated in FIGS. 3 and 4. In this case, the single device 10 is replaced either by a series arrangement or a parallel arrangement of the respective pyro-electric material sections or areas 13.

The more pyro-electric material sections or areas 13 a device 10 comprises, the more electric power the apparatus 100 can extract. Small devices can provide an output power in the range of about 1 Watt, whereas an array, like the one depicted in FIGS. 6A, 6B, can deliver up to 100 Watt output power.

The pyro-electric material sections or areas 13 may have a thickness of a few millimeters up to a few centimeters. Their surface plane might have a size of a few square millimeter up to several square centimeter.

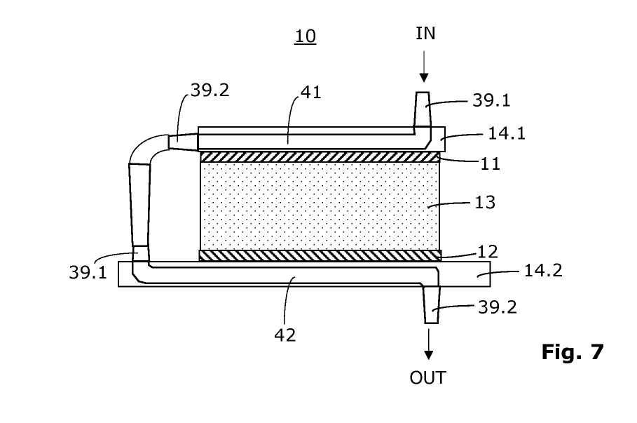

FIG. 7 shows a schematic representation of another device 10. The device 10 comprises a pyro-electric material 13, a first electrode 11 and a second electrode 12. These elements 11, 12, 13 of the device 10 are positioned in-between two heat-exchanging structures 14.1, 14.2. The heat-exchanging structure 14.1 comprises a first access point 39.1. This first access point 39.1 is in fluid connection with an internal channel 41 which is in fluid connection with a second access point 39.2. The heat-exchanging structure 14.2 comprises a first access point 39.1 and a second access point 39.2. The heat-exchanging structure 14.2 is connected in series. This means that the second access point 39.2 of the first heat-exchanging structure 14.1 is connected to the first access point 39.1 of the second heat-exchanging structure 14.2. The first access point 39.1 of the second heat-exchanging structure 14.2 is in fluid connection with an internal channel 42 which is in fluid connection with the second access point 39.2. A fluid (for instance water or oil) is fed through the two heat-exchanging structures 14.1, 14.2, as indicated by the arrows IN and OUT.

It will be understood that many variations could be adopted based on the specific structure hereinbefore described without departing from the scope of the invention as defined in the following claims.

| | |
|---|---|
| device | 10 |
| first electrically conducting electrode | 11 |
| second electrically conducting electrode | 12 |
| pyro-electric material | 13 |
| heat-exchanging structure | 14 |
| heat-exchanging structures | 14.1, 14.2 |
| electric oscillator circuitry | 20 |
| first oscillator | 30 |
| transformer | 31 |
| core | 32 |
| rectifier | 33 |
| gate | 34 |
| drain | 35 |
| source | 36 |
| load element | 37 |
| transformer | 38 |
| access points | 39.1, 39.2 |
| second oscillator (resonance circuit) | 40 |
| internal channel | 41 |
| internal channel | 42 |
| Apparatus | 100 |
| Alternating current | AC |
| Pyroelectric capacitor | C1(T) |
| capacitor | C1 |
| capacitor | C2 |
| capacitors | CI, CII, CII, CIV |
| Direct current | DC |
| first resonance frequency | f1 |
| second resonance frequency | f2 |
| Load winding | La |
| Winding/inductor | Lb |
| Winding/inductor | Lc |
| first inductor | L1 |
| second winding | L2 |
| Nodes | n1, n2, n3, n4, n5, n6 |
| first electric output | O1 |
| second electric output | O2 |
| Output nodes | O3, O4 |
| Heat (quantity) | W |
| Supercapacitor | SC |
| Supercapacitor | SC1 |
| transistor | T1 |

1. Apparatus (100) comprising a device (10) with
a first electrically conducting electrode (11),
a second electrically conducting electrode (12), said electrodes (11, 12) being spaced apart,
a pyro-electric material (13) to which said electrodes (11, 12) are attached/applied,
at least one heat-exchanging structure (14) being thermally coupled to said pyro-electric material (13),
said apparatus (100) further comprising
an electric oscillator circuitry (20),
said device (10) being electrically connectable to the electric oscillator circuitry (20) so as to provide an oscillation of said pyro-electric material (13).

2. Apparatus (100) according to claim 1, characterized in that it further comprises a first inductor (L1) which is coupled to said device (10) so as to form a first oscillator (30).

3. Apparatus (100) according to claim 1, wherein said electric oscillator circuitry (20) comprises a second oscillator (40) which comprises a capacitor (C2) and a second inductor (L2).

4. Apparatus (100) according to claim 3, wherein said first oscillator (30) and said second oscillator (40) are coupled by means of conductive connections so that these two oscillators (30, 40) can be caused to jointly oscillate.

5. Apparatus (100) according to claim 3, wherein said first oscillator (30) and said second oscillator (40) are arranged in series.

6. Apparatus (100) according to claim 3, wherein said first oscillator (30) has a first resonance frequency (f1) and said second oscillator (40) has a second resonance frequency (f2), and wherein said first resonance frequency (f1) and said second resonance frequency (f2) are different.

7. Apparatus (100) according to claim 6, wherein the first resonance frequency (f1) and the second resonance frequency (f2) are both in the range between 5 kHz and 500 kHz.

8. Apparatus (100) according to claim 6, wherein the difference of the resonance frequencies (f1, f2) is between 5% and 0.1%.

9. Apparatus (100) according to claim 3, wherein said first oscillator (30) and said second oscillator (40) are caused to oscillate with a beat frequency between 10 and 100 times per second.

10. Apparatus (100) according to claim 3, further comprising a transistor (T1) being arranged between said first oscillator (30) and said second oscillator (40).

11. Apparatus (100) according to claim 10, wherein said transistor (T1) can be switched so that current flows from said first oscillator (30) into said second oscillator (40).

12. Apparatus (100) according to claim 10, further comprising a supercapacitor (SC1) and a rectifier (33), wherein said rectifier (33) is arranged so as to provide a DC output signal and wherein said DC output signal is applied to said supercapacitor (SC1).

13. Apparatus (100) according to claim 1, characterized in that it further comprises a capacitor (SC1), preferably a supercapacitor, being coupled to said device (10), so that the capacitor (SC1) is enabled to provide energy for said oscillation.

14. Apparatus (100) according to claim 1, wherein electric energy is being made available at said electric nodes (O1, O2), when exposing said device (10) to a heat source or flow.

15. Apparatus (100) according to claim 1, wherein said electric oscillator circuitry (20) and said device (10) are electrically coupled so as to cause the pyro-electric material (13) to oscillate.

16. Apparatus (100) according to claim 1, wherein the pyro-electric material (13) is caused to oscillate at a frequency above 50 kHz.

17. Apparatus (100) according to claim 1, wherein said electric oscillator circuitry (20) drives said device (10) in a non-linear mode, preferably by providing an ascending slope of the amplitude of the oscillation which brings the device (10) in the non-linear mode.

18. Apparatus (100) according to claim 1, wherein a solid state crystal serves as pyro-electric material (13).

19. Apparatus (100) according to claim 18, wherein a silicate mineral, preferably a crystal boron silicate mineral, or Tourmaline serves as pyro-electric material (13).

20. Apparatus (100) according to claim 18, wherein a Triglycine sulfate crystal serves as pyro-electric material (13).

21. Apparatus (100) according to claim 18, wherein a Perowskit-Oxide crystal serves as pyro-electric material (13).

22. Apparatus (100) according to claim 1, wherein said heat-exchanging structure (14) comprises aluminum or copper.

23. Use of a device (10) as thermal power cell, said device (10) comprising
a first electrically conducting electrode (11),
a second electrically conducting electrode (12), said electrodes (11, 12) being spaced apart,
a pyro-electric material (13) to which said electrodes (11, 12) are attached/applied, and
at least one heat-exchanging structure (14) being thermally coupled to said pyro-electric material (13).

24. The use according to claim 23, wherein the device (10) is connected to an oscillator (20) which is designed to cause said pyro-electric material (13) to oscillate.
